(19) United States
(12) Patent Application Publication
(10) Pub. No.: US 2015/0228788 A1
(43) Pub. Date: Aug. 13, 2015

(54) STRESS MEMORIZATION PROCESS AND SEMICONDUCTOR STRUCTURE INCLUDING CONTACT ETCH STOP LAYER

(71) Applicant: United Microelectronics Corp., Hsin-Chu City (TW)

(72) Inventors: Chun-Feng Chen, Tainan City (TW); Wen-Yu Yang, Pingtung County (TW); Yu-Cheng Tung, Kaohsiung City (TW); Chun-Hsien Huang, Kaohsiung City (TW); Hui-Shen Shih, Changhua County (TW); Shih-Chang Chang, Tainan City (TW)

(73) Assignee: United Microelectronics Corp., Hsin-Chu City (TW)

(21) Appl. No.: 14/179,563

(22) Filed: Feb. 13, 2014

(51) Int. Cl. H01L 29/78; H01L 21/28; H01L 29/66

(52) U.S. Cl. CPC H01L 29/7847; H01L 29/66477; H01L 21/28008

(57) ABSTRACT

A stress memorization process including the following step is provided. A gate is formed on a substrate. A low-k dielectric layer with a dielectric constant lower than 3 is formed to entirely cover the gate and the substrate. A stress layer is formed to entirely cover the low-k dielectric layer. The stress layer and the low-k dielectric layer are removed. Moreover, a semiconductor structure including a contact etch stop layer is provided. A gate is disposed on a substrate. A porous layer entirely covers the gate and the substrate. A contact etch stop layer entirely covers the porous layer, wherein the thickness of the porous layer is thinner than the thickness of the contact etch stop layer.

### BACKGROUND OF THE INVENTION

1. Field of the Invention

The present invention relates generally to a stress memorization process and a semiconductor structure including a contact etch stop layer, and more specifically to a stress memorization process and a semiconductor structure including a contact etch stop layer, which applies a low-k dielectric layer or a porous layer.

2. Description of the Prior Art

A conventional MOS transistor generally includes a semiconductor substrate, such as silicon, a source region, a drain region, a channel positioned between the source region and the drain region, and a gate located above the channel. The gate is composed of a gate dielectric layer, a gate conductive layer positioned on the gate dielectric layer, and a plurality of spacers positioned on the sidewalls of the gate conductive layer. Generally, for a given electric field across the channel of a MOS transistor, the amount of current that flows through the channel is directly proportional to a mobility of the carriers in the channel. Therefore, how to improve the carrier mobility so as to increase the speed performance of MOS transistors has become a major topic for study in the semiconductor field.

One conventional approach for enhancing the carrier mobility is to form mechanical stresses within the channel region. For example, mechanical stresses within the channel region can be induced in many ways such as through stresses created by films in a form of stress layer or contact etch stop layer (CESL). However, the ways of forming these films such as stress layers or contact etch stop layers extremely affect stresses induced in the channel region.

### SUMMARY OF THE INVENTION

The present invention provides a stress memorization process and a semiconductor structure including a contact etch stop layer, which applies a low-k dielectric layer or a porous layer as a buffer layer to improve induced stresses.

The present invention provides a stress memorization process including the following step. A gate is formed on a substrate. A low-k dielectric layer with a dielectric constant lower than 3 is formed to entirely cover the gate and the substrate. A stress layer is formed to entirely cover the low-k dielectric layer. The stress layer and the low-k dielectric layer are removed.

The present invention provides a semiconductor structure including a contact etch stop layer. A gate is disposed on a substrate. A porous layer entirely covers the gate and the substrate. A contact etch stop layer entirely covers the porous layer, wherein the thickness of the porous layer is thinner than the thickness of the contact etch stop layer.

According to the above, the present invention provides a stress memorization process and a semiconductor structure including a contact etch stop layer, which applies a low-k dielectric layer or a porous layer as a buffer layer between a stress layer or a contact etch stop layer and a substrate to improve buffering and induced stresses.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-5 schematically depict cross-sectional views of a stress memorization process according to an embodiment of the present invention.

FIGS. 6-9 schematically depict cross-sectional views of a semiconductor structure including a contact etch stop layer according to an embodiment of the present invention.

FIG. 10 schematically depicts a curve diagram of dielectric constant versus porosity of a dielectric layer according to an embodiment of the present invention.

### DETAILED DESCRIPTION

FIGS. 1-5 schematically depict cross-sectional views of a stress memorization process according to an embodiment of the present invention.

As shown in FIG. 1, a substrate 110 is provided. The substrate 110 may be a semiconductor substrate such as a silicon substrate, a silicon containing substrate, a III-V group-on-silicon (such as GaN-on-silicon) substrate, a graphene-on-silicon substrate or a silicon-on-insulator (SOI) substrate. A gate G is formed on the substrate 110. The gate G may include a buffer layer 122, a dielectric layer 124, a barrier layer (not shown), an electrode layer 126 and a cap layer 128 from bottom to top, but it is not limited thereto. More precisely, a buffer layer (not shown), a dielectric layer (not shown), a barrier layer (not shown), an electrode layer (not shown) and a cap layer (not shown) are sequentially and entirely formed on the substrate 110 and then are patterned to form the gate G, but it is not limited thereto.

The buffer layer 122 may be an oxide layer formed by a thermal oxide process or a chemical oxide process or others. The buffer layer 122 is located between the gate dielectric layer 124 and the substrate 110 to buffer the gate dielectric layer 124 and the substrate 110. A gate-last for high-k first process is applied in this embodiment, so that the gate dielectric layer 124 is a gate dielectric layer having a high dielectric constant, which may be the group selected from hafnium oxide (HfO₂), hafnium silicon oxide (HfSiO₄), hafnium silicon oxynitride (HfSiON), aluminum oxide (Al₂O₃), lanthanum oxide (La₂O₃), tantalum oxide (Ta₂O₅), yttrium oxide (Y₂O₃), zirconium oxide (ZrO₂), strontium titanate oxide (SrTiO₃), zirconium silicon oxide (ZrSiO₄), hafnium zirconium oxide (HfZrO₄), strontium bismuth tantalite (SrBi₂Ta₂O₉, SBT), lead zirconate titanate (PbZrₓTi₁-xO₃, PZT) and barium strontium titanate (BaₓSr₁-xTiO₃, BST), but it is not limited thereto. In another embodiment, as a gate-last for high-k last process is applied, the gate dielectric layer 124 will be removed in later processes and then a gate dielectric layer having a high dielectric constant is formed. Therefore, the material of the gate dielectric layer 124 may be just a sacrificial material suitable for being removed in later processes. The barrier layer (not shown) is located on the gate dielectric layer 124 to prevent above disposed metals from diffusing downwards to the gate dielectric layer 124 and from polluting the gate dielectric layer 124. The barrier layer may be a single layer structure or a multilayer structure composed of tantalum nitride (TaN) or titanium nitride (TiN) or others. In this embodiment, the electrode layer 126 is a dummy gate and made of polysilicon, but it is not limited thereto. The cap layer 128 may be a single layer or a multilayer composed of a nitride layer or an oxide layer or others used for being a patterned hard mask, but it is not limited thereto.

A spacer (not shown) for forming a lightly doped source/drain region may be formed on the substrate 110 beside the gate G, and then the lightly doped source/drain region (not shown) is aligned and formed in the substrate 110 beside the spacer. The lightly doped source/drain region may be doped with pentavalent ions such as phosphorous ions for forming an N-type semiconductor structure; or, may be doped with trivalent ions such as boron ions for forming a P-type semiconductor structure. The lightly doped source/drain region has a dopant concentration lower than a later formed source/drain region.

Then, an epitaxial spacer 130 may be further formed beside the spacer or may be formed to replace the spacer for forming an epitaxial layer. Thus, an epitaxial layer 132 is self-aligned and formed in the substrate 110 beside the epitaxial spacer 130. The epitaxial layer 132 may be a silicon germanium epitaxial layer or others for forming a P-type epitaxial layer; or, may be a silicon carbide epitaxial layer or silicon phosphorous epitaxial layer etc, for forming an N-type epitaxial layer.

A spacer 140 is formed on the substrate 110 beside the gate G for forming a source/drain region 142. The method of forming the spacer 140 may include the following step. A spacer material (not shown) is conformally formed on the substrate 110 and the gate G, and then the spacer material is patterned to form the spacer 140. In this embodiment, the spacer 140 is a single spacer; but in another embodiment, the spacer 140 may be a multilayer spacer such as a dual spacer, depending upon the needs. The spacer 140 may be composed of silicon nitride or silicon oxide or others.

Thereafter, an ion implantation process is performed to automatically align and form the source/drain region 142 in the substrate 110 beside the gate G. The source/drain region 142 may be doped with pentavalent ions such as phosphorous ions for forming an N-type semiconductor structure; or, may be doped with trivalent ions such as boron ions for forming a P-type semiconductor structure. It is noted that, an annealing process for activating the source/drain region 142 is not performed at this time and will be performed in later processes after a stress layer is formed instead.

Accordingly, the order of forming the lightly doped source/drain region, the epitaxial layer 132 and the source/drain regions 142 is not restricted thereto, depending upon the needs.

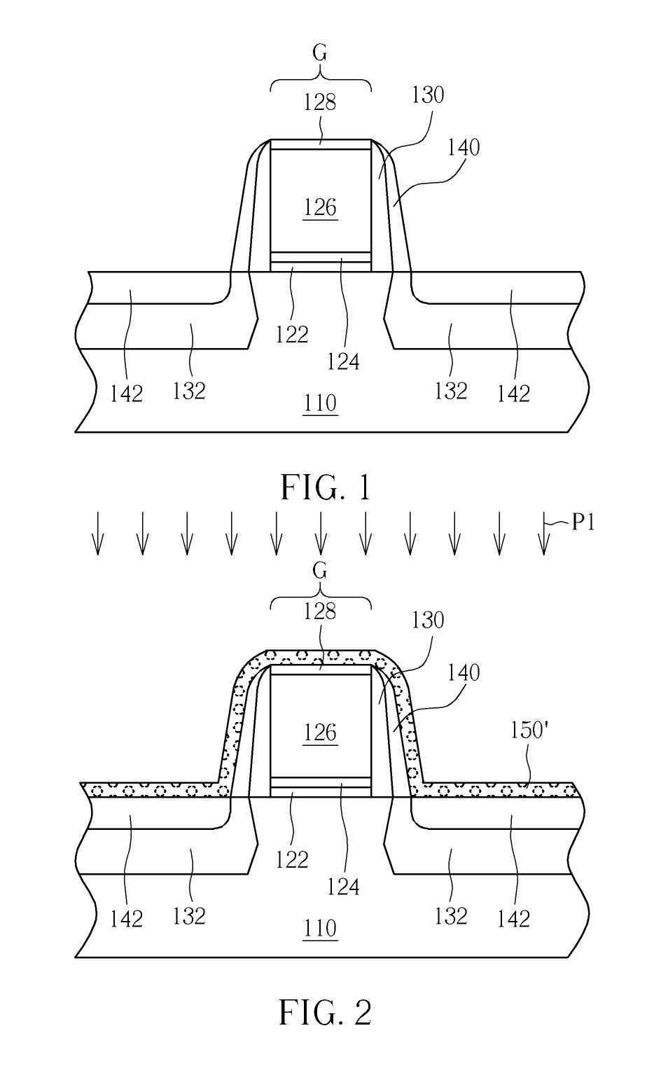

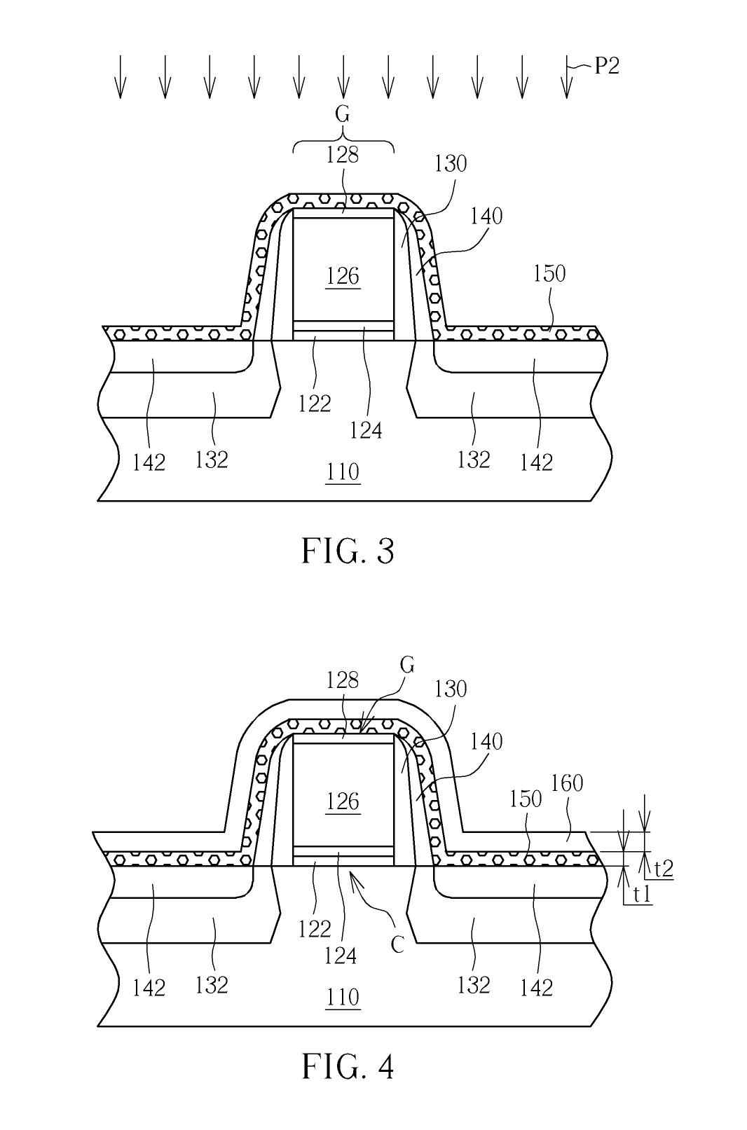

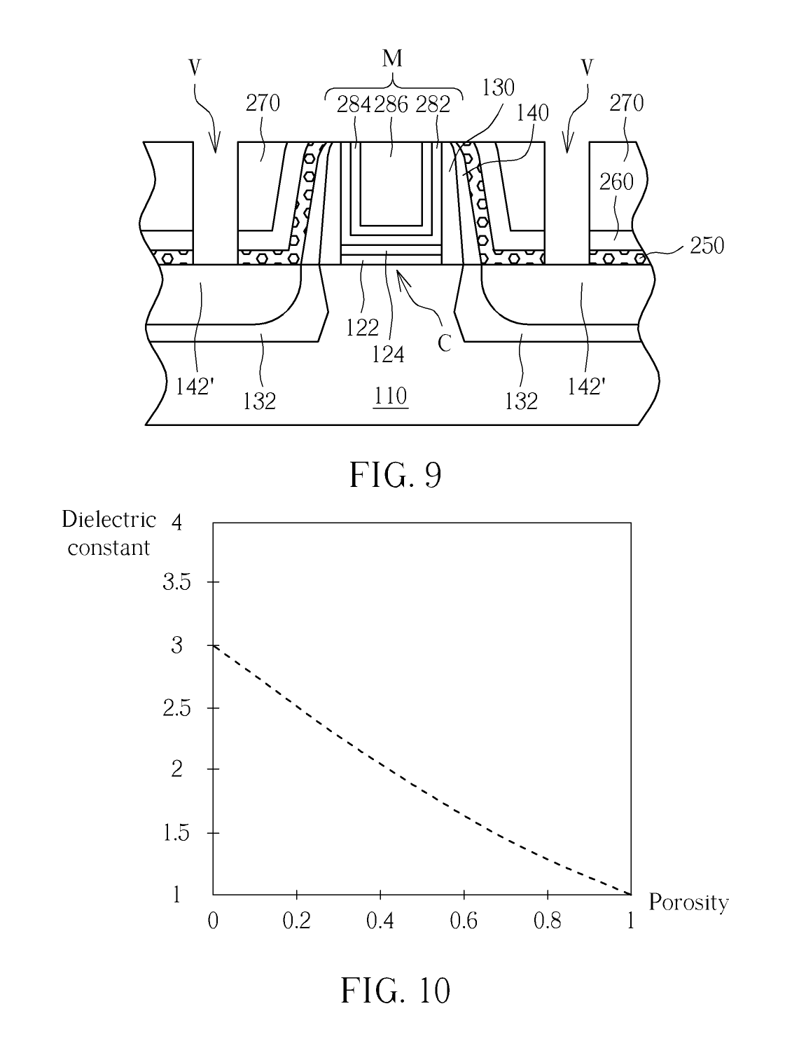

As shown in FIGS. 2-3, a low-k dielectric layer 150 is formed to entirely cover the gate G and the substrate 110. The low-k dielectric layer 150 preferably includes a porous layer for improving stress induced by a later formed stress layer thereon. Still preferably, the low-k dielectric layer 150 has a dielectric constant lower than 3 for forming a porous layer to be a porous-rich layer. FIG. 10 schematically depicts a curve diagram of dielectric constant versus porosity of a dielectric layer according to an embodiment of the present invention. As shown in FIG. 10, as a dielectric layer has a lower dielectric constant, the porosity of the dielectric layer is higher. However, as the porosity of the dielectric layer is higher, the mechanical support is lower. Furthermore, the stress of the low-k dielectric layer 150 is preferably under 100 MPa for the low-k dielectric layer has a thickness of 1000 angstroms, so that the stress of the low-k dielectric layer 150 is small enough and will not affect stress induced by an above formed stress layer.

More precisely, the low-k dielectric layer 150 may be formed by performing a deposition process P1 such as a chemical vapor deposition (CVD) process or a plasma enhance chemical vapor deposition (PECVD) process for depositing a pre-layer 150′ having desired materials and micro-structures as shown in FIG. 2, and then performing a treatment process P2 to modify the pre-layer 150′ such as porousing the pre-layer 150′ to form the low-k dielectric layer 150 as shown in FIG. 3, but it is not limited thereto. Or, the low-k dielectric layer 150 may be formed by depositing a pre-layer 150′ by having two precursors imported as shown in FIG. 2, and then performing a treatment process P2 to form the low-k dielectric layer 150 as shown in FIG. 3. In one case, the pre-layer 150′ is a non-porous layer and one of the two precursors, however, may include a porogen as shown in FIG. 2. Therefore, as the treatment process P2 is performed on the pre-layer 150′, the low-k dielectric layer 150 being a porous layer is formed due to the porogen deposited in the pre-layer 150′ is removed by the treatment process P2, but it is not limited thereto.

For instance, the low-k dielectric layer 150 may be a porous organic silicate glass layer. Thus, the two precursors may include DiEthoxyMethylSilane and organic porogen and the chemical formula of the organic porogen may be CₓH_{y}, but it is not limited thereto. Moreover, in a preferred embodiment, the treatment process P2 may include a porous process, a curing process or an ultraviolet (UV) light illumination process, but it is not restricted thereto.

Thereafter, as shown in FIG. 4, a stress layer 160 is formed to entirely cover the low-k dielectric layer 150. The stress layer 160 may be a doped nitride layer or a carbon containing silicon nitride layer, but it is not limited thereto. Therefore, the low-k dielectric layer 150 is disposed between the stress layer 160 and the gate G and substrate 110 for serving as a buffer layer. It is emphasized that, due to the low-k dielectric layer 150 having a dielectric constant lower than 3 or being a porous layer, the low-k dielectric layer 150 can not only be an improved buffer layer due to having a soft material property but also can further improve stresses induced by the stress layer 160. Preferably, the thickness t1 of the low-k dielectric layer 150 is thinner than the thickness t2 of the stress layer 160, thus the low-k dielectric layer 150 can maintain the capability of the stress layer 160 inducing a channel region C. Still preferably, the thickness t1 of the low-k dielectric layer 150 is in a range of 90˜110 angstroms while the thickness t2 of the stress layer 160 is in a range of 400˜500 angstroms.

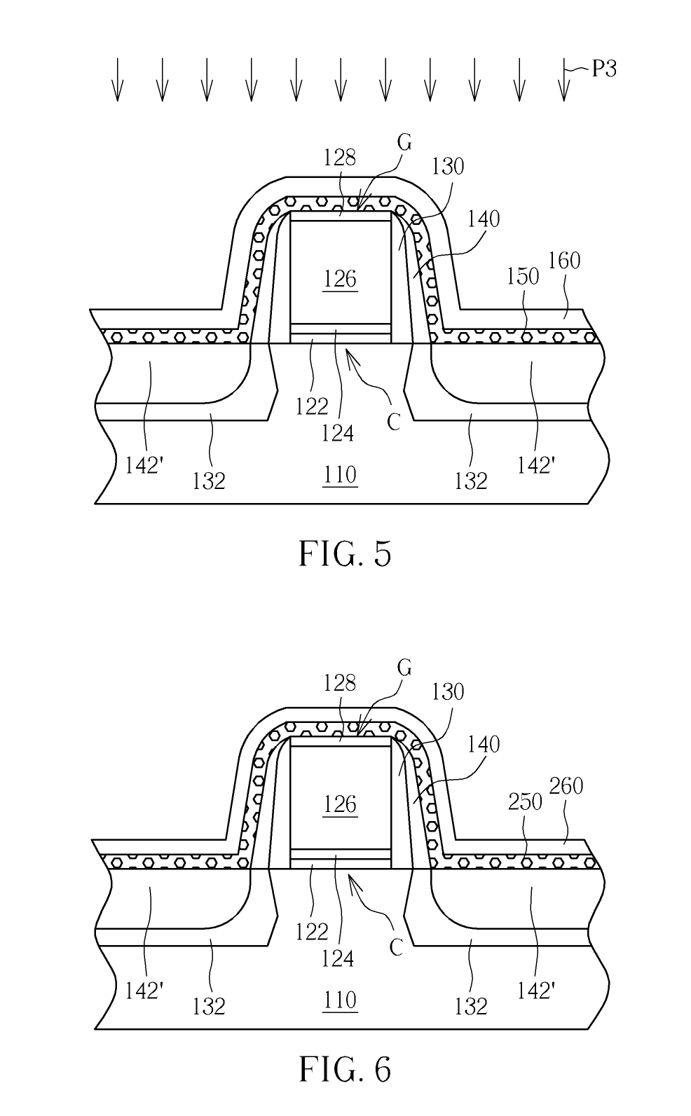

As shown in FIG. 5, an annealing process P3 is performed after the stress layer is formed, thereby stress induced by the stress layer 160 is kept in the channel region C. Besides, as the stress induced by the stress layer 160 is kept in the channel region C, the source/drain region 142 is also activated by the annealing process P3, therefore the source/drain region 142′ is formed. Since the annealing process P3 is performed after the source/drain region 142 and the stress layer 160 are formed, processes can be simplified and costs can be reduced due to only a single annealing process P3 being carried out to achieve the two purposes, but it is not limited thereto. In another embodiment, an annealing process may be performed right after the source/drain region 142 is formed to activate it, and then the annealing process P3 is performed to keep stresses in the channel region C and further activate source/drain region 142 again.

Then, the stress layer 160 and the low-k dielectric layer 150 are removed after stresses are kept in the channel region C, as similar to FIG. 1. In one embodiment, the stress layer 160 may be removed by an etching process such as a wet etching process containing hot phosphoric acid, which has a higher etching rate to the stress layer 160 including nitride than to the low-k dielectric layer 150; then, the low-k dielectric layer 150 may be removed by an etching process such as a wet etching process containing dilute hydrofluoric acid (DHF), a standard cleaning 1 (SC1) process or a standard cleaning 2 (SC2) process etc, but it is not limited thereto. The stress layer 160 and the low-k dielectric layer 150 may be removed individually by processes having etching selectivity to these two layers for preventing over-etching, or the stress layer 160 and the low-k dielectric layer 150 may be removed by single process for saving processing time and reducing processing costs, depending upon practical needs.

Thereafter, later semiconductor processes such as performing a silicide process to form a metal silicide on the source/drain region 132, forming a contact etch stop layer on the gate G and the substrate 110, and forming interconnections on the gate G and the substrate 110 may be performed.

According to the above, the present invention can be applied in a stress memorization process. Moreover, the present invention can also be applied in many other semiconductor processes or semiconductor structures. For example, the present invention can be applied to a semiconductor structure including a contact etch stop layer as illustrated below. Furthermore, the semiconductor structure including a contact etch stop layer can also be applied after said stress memorization process of the present invention is applied. FIGS. 6-9 schematically depict cross-sectional views of a semiconductor structure including a contact etch stop layer according to an embodiment of the present invention.

The previous processes in this embodiment are similar to the previous processes of the first embodiment as described above and depicted in FIGS. 1-3. As shown in FIG. 1, the gate G is formed on the substrate 110, the spacer 140 is formed on the substrate 110 beside the gate G and thus the source/drain region 132 is formed in the substrate 110 beside the spacer 140, the epitaxial spacer 140 is formed beside the spacer 140, and then the epitaxial layer 142 is thus formed in the substrate 110 beside the epitaxial spacer 140. Then, a salicide process (not shown) may be selectively performed to form a metal silicide (not shown) on the source/drain region 132.

As shown in FIG. 6, a porous layer 250 entirely covers the gate G and the substrate 110 for buffering a later formed contact etch stop layer thereon and even improving stress induced by the contact etch stop layer. The porous layer 250 preferably includes a low-k dielectric layer for forming a porous layer. Still preferably, the porous layer 250 has a dielectric constant lower than 3 for forming a porous layer to be a porous-rich layer. FIG. 10 schematically depicts a curve diagram of dielectric constant versus porosity of a dielectric layer according to an embodiment of the present invention. As shown in FIG. 10, as a dielectric layer has a lower dielectric constant, the porosity of the dielectric layer is higher. However, as the porosity of the dielectric layer is higher, the mechanical support is lower. Furthermore, the stress of the porous layer 250 is preferably under 100 MPa for the porous layer 250 has a thickness of 1000 angstroms, so that the stress of the porous layer 250 is small enough and will not affect stress induced by an above formed contact etch stop layer.

More precisely, the porous layer 250 may be formed similar to the low-k dielectric layer 150 of the first embodiment as shown in FIGS. 2-3. That is, the porous layer 250 may be formed by performing a deposition process P1 such as a chemical vapor deposition (CVD) process or a plasma enhance chemical vapor deposition (PECVD) process for depositing a pre-layer 150′ having desired materials and micro-structures, and then performing a treatment process P2 to modify the pre-layer 150′ such as porousing the pre-layer 150′ to form the porous layer 250, but it is not limited thereto. Or, the porous layer 250 may be formed by depositing a pre-layer 150′ by having two precursors imported, and then performing a treatment process P2 to form the porous layer 250. In one case, the pre-layer 150′ is a non-porous layer and one of the two precursors, however, may include a porogen. Therefore, as the treatment process P2 is performed on the pre-layer 150′, the porous layer 250 being a porous layer is formed due to the porogen deposited in the pre-layer 150′ being removed by the treatment process P2, but it is not limited thereto.

For instance, the porous layer 250 may be a porous organic silicate glass layer. Thus, the two precursors may include DiEthoxyMethylSilane and organic porogen and the chemical formula of the organic porogen may be CₓH_{y}, but it is not limited thereto. Moreover, in a preferred embodiment, the treatment process P2 may include a porous process, a curing process or a ultraviolet (UV) light illumination process, but it is not restricted thereto.

Please refer to FIG. 6 again, a contact etch stop layer (CESL) 260 is formed to cover the porous layer 250. The contact etch stop layer 260 may be a doped nitride layer or a stress layer, but it is not limited thereto. Therefore, the porous layer 250 is disposed between the contact etch stop layer 260 and the gate G and substrate 110 for serving as a buffer layer. It is emphasized that, the porous layer 250 can not only be an improved buffer layer due to having a soft material property but also can further improve stresses induced by the contact etch stop layer 260. Preferably, the thickness t3 of the porous layer 250 is thinner than the thickness t4 of the contact etch stop layer 260, thus the porous layer 250 can maintain the capability of the contact etch stop layer 260 inducing a channel region C. Still preferably, the thickness t3 of the porous layer 250 is in a range of 90˜110 angstroms while the thickness t4 of the contact etch stop layer 260 is in a range of 400˜500 angstroms.

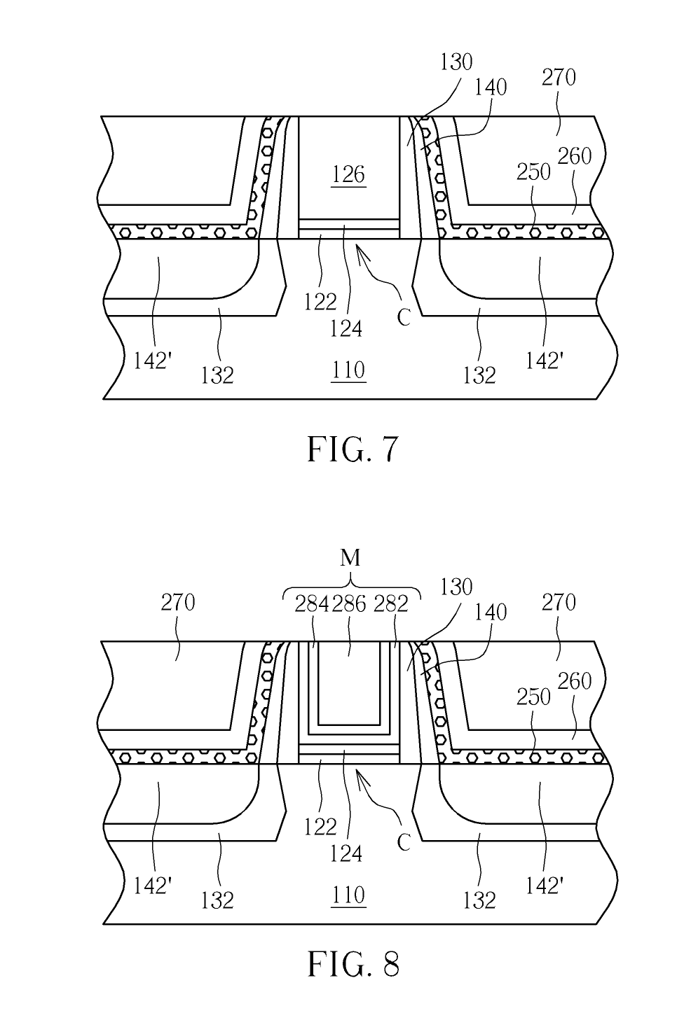

As shown in FIG. 7, an interdielectric layer (not shown) entirely covers the contact etch stop layer 260, and then is planarized until the electrode layer 126 is exposed, thereby an interdielectric layer 270 is formed. The interdielectric layer 270 may be an oxide layer, but it is not limited thereto.

As shown in FIG. 8, the electrode layer 126 is replaced with a metal gate M including a work function metal layer 282, a barrier layer 284 and a low resistivity 286. The work function metal layer 282 may be a single layer or a multilayer structure, composed of titanium nitride (TiN), titanium carbide (TiC), tantalum nitride (TaN), tantalum carbide (TaC), tungsten carbide (WC), titanium aluminide (TiAl) or aluminum titanium nitride (TiAlN) or others. The barrier layer 284 may be a single layer or a multilayer structure composed of tantalum nitride (TaN) or titanium nitride (TiN) or others. The low resistivity material 286 may be composed of low resistivity materials such as aluminum, tungsten, titanium aluminum (TiAl) alloy, cobalt tungsten phosphide (CoWP) or others.

Thereafter, contact holes V are formed in the interdielectric layer 270, the contact etch stop layer 260 and the porous layer 250, thereby exposing the source/drain 132′, as shown in FIG. 9. Then, contact plugs (not shown) are formed in the contact holes V to electrically connect the source/drain 132′ outwards. The contact plugs may be composed of copper, aluminum or tungsten or others. Furthermore, a salicide process (not shown) may be performed at this time instead of performing before the contact holes V are formed. Thus, a metal silicide (not shown) can be formed only in the contact holes V, but it is not limited thereto.

To summarize, the present invention provides a stress memorization process and a semiconductor structure including a contact etch stop layer, which applies a low-k dielectric layer or a porous layer as a buffer layer between a stress layer or a contact etch stop layer and a substrate to improve buffering and induced stresses. Moreover, the low-k dielectric layer or the porous layer has a dielectric constant lower than 3 for forming a porous-rich layer. The thickness of the low-k dielectric layer is thinner than the thickness of the stress layer; or the thickness of the porous layer is thinner than the thickness of the contact etch stop layer.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A stress memorization process, comprising:
forming a gate on a substrate;
forming a low-k dielectric layer with a dielectric constant lower than 3 entirely covering the gate and the substrate;
forming a stress layer entirely covering the low-k dielectric layer; and
removing the stress layer and the low-k dielectric layer.

2. The stress memorization process according to claim 1, wherein the low-k dielectric layer comprises a porous layer.

3. The stress memorization process according to claim 1, wherein the stress of the low-k dielectric layer is under 100 MPa for the low-k dielectric layer has a thickness of 1000 angstroms.

4. The stress memorization process according to claim 1, wherein the low-k dielectric layer is formed by performing a CVD process or a PECVD process, and then performing a treatment process.

5. The stress memorization process according to claim 1, wherein the step of forming the low-k dielectric layer comprises:
depositing a pre-layer by having two precursors imported; and
performing a treatment process to form the low-k dielectric layer.

6. The stress memorization process according to claim 5, wherein the pre-layer is a non-porous layer.

7. The stress memorization process according to claim 5, wherein one of the two precursors comprises a porogen.

8. The stress memorization process according to claim 5, wherein the treatment process comprises a porous process, a curing process or a UV light illumination process.

9. The stress memorization process according to claim 5, wherein the two precursors comprise DiEthoxyMethylSilane and organic porogen.

10. The stress memorization process according to claim 9, wherein the chemical formula of the organic porogen is CₓH_{y}.

11. The stress memorization process according to claim 1, wherein the low-k dielectric layer comprises a porous organic silicate glass layer.

12. The stress memorization process according to claim 1, further comprising:
performing an annealing process after the stress layer is formed.

13. The stress memorization process according to claim 1, wherein the thickness of the low-k dielectric layer is thinner than the thickness of the stress layer.

14. A semiconductor structure comprising a contact etch stop layer, comprising:
a gate disposed on a substrate;
a porous layer entirely covering the gate and the substrate; and
a contact etch stop layer entirely covering the porous layer, wherein the thickness of the porous layer is thinner than the thickness of the contact etch stop layer.

15. The semiconductor structure comprising a contact etch stop layer according to claim 14, wherein the porous layer comprises a low-k dielectric layer.

16. The semiconductor structure comprising a contact etch stop layer according to claim 15, wherein the low-k dielectric layer has a dielectric constant lower than 3.

17. The semiconductor structure comprising a contact etch stop layer according to claim 14, wherein the porous layer comprises a porous organic silicate glass layer.

18. The stress memorization process according to claim 14, further comprising:
a source/drain located in the substrate beside the gate and under the contact etch stop layer; and
a contact hole in the contact etch stop layer and exposing the source/drain.

19. The semiconductor structure comprising a contact etch stop layer according to claim 14, wherein the thickness of the porous layer is in a range of 90˜110 angstroms while the thickness of the contact etch stop layer is in a range of 400˜500 angstroms.

20. The semiconductor structure comprising a contact etch stop layer according to claim 14, wherein the stress of the porous layer is under 100 MPa for the porous layer has a thickness of 1000 angstroms.
